(19) United States
(12) Patent Application Publication
(10) Pub. No.: US 2023/0006374 A1
(43) Pub. Date: Jan. 5, 2023

(54) MEMORY ON PACKAGE WITH INTERPOSER WITH COMPRESSION-BASED CONNECTORS

(71) Applicant: Intel Corporation, Santa Clara, CA (US)

(72) Inventors: Min Suet LIM, Gelugor (MY); Luis Carlos ALVAREZ MATA, Cartago (CR); Ankita TIWARI, Sunnyvale, CA (US); Xiang LI, Portland, OR (US); Jun LIAO, Portland, OR (US)

(21) Appl. No.: 17/899,379

(22) Filed: Aug. 30, 2022

(51) Int. Cl. H01R 12/71; H01L 23/00; H01L 23/32; H01L 23/40; H01L 25/065; H01R 13/24

(52) U.S. Cl. CPC H01R 12/714; H01L 24/72; H01L 23/32; H01L 23/4006; H01L 25/0652; H01R 13/2435; H01L 2224/72; H01L 2924/1436; H01L 2023/4087; H01R 13/621

(57) ABSTRACT

A system connects a board to a substrate through an interposer board having compressible connectors through the interposer board. The connectors through the interposer board are compression-based connector pins that extends above and below the interposer board to make electrical contact between the board and the substrate. The system can include a plate to secure the board to the substrate and compress the compression-based connectors of the interposer board.

### FIELD

Descriptions are generally related to interconnects, and more particular descriptions are related to compressive connectors.

### BACKGROUND

System memory plays an important role in a computer system. When more system memory can be placed closer to the compute die with a faster interconnect, the compute die can experience lower memory access latency, while decreasing system layout. Memory on package (MOP) is an architecture that provides memory on a substrate with the compute die. MOP architecture can solder a memory die directly onto the package.

When the memory is directly soldered onto the compute substrate, the memory is not removable, and thus cannot be replaced in the event of failure or for purposes of upgrade. Whatever memory is shipped with a system is fixed, and a failure will result in the need to replace the entire compute substrate.

Additionally, when used in high-performance scenarios involving significant numbers of memory access, the memory devices run much hotter than the compute tiles. The high temperature of the memory on the substrate can result in thermal crosstalk between the memory die and the compute die. Thermal interference from the memory can negatively impact the performance of the compute die.

Connector alternatives to direct-attach of the memory can result in large pin pitch or increased system Z-height, which limits how much system size can be reduced. The connector alternatives also have exposed edge contacts, which can oxidize the connections, degrading signal performance. Additionally, connector pins can cause electromagnetic interference (EMI), creating signal degradation as memory systems use increasingly higher signaling frequencies.

### BRIEF DESCRIPTION OF THE DRAWING

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIGS. 1A-1C illustrates diagrams of an example of a circuit having compressible interconnects to connect a memory module.

FIG. 1D illustrates diagrams of an example the circuit with a plate to compress the interconnects to connect a memory module.

FIGS. 1E-1F illustrates diagrams of an example of a circuit having compressible interconnects to connect a memory module with a CAMM.

FIG. 1G illustrates diagrams of an example the circuit with a plate to compress the interconnects to connect a memory module with the CAMM.

FIG. 2 illustrates diagrams of an example of a system with memory connected to a compute substrate with compressible interconnects.

FIG. 3 is a block diagram of an example of a system in which an interposer has C-shaped compression connectors.

FIGS. 4A-4B are cutaway view diagrams of an example of a memory module to connect to a substrate with an interposer having compression-based connectors.

FIGS. 5A-5B illustrate an example of a closed loop connector pin that is open when uncompressed and closed when compressed.

FIGS. 6A-6B illustrate an example of a closed loop connector pin that is closed when uncompressed and closed when compressed.

FIGS. 7A-7C illustrate an example of a connector enclosed in a cylinder.

FIG. 8 is a block diagram of an example of a computer system with a connector having an interposer with compression-based connectors.

FIG. 9 is a block diagram of an example of a memory subsystem in which a connector having an interposer with compression-based connectors can be implemented.

FIG. 10 is a block diagram of an example of a computing system in which a connector having an interposer with compression-based connectors can be implemented.

FIG. 11 is a block diagram of an example of a mobile device in which a connector having an interposer with compression-based connectors can be implemented.

Descriptions of certain details and implementations follow, including non-limiting descriptions of the figures, which may depict some or all examples, and well as other potential implementations.

### DETAILED DESCRIPTION

As described herein, a system connects a printed circuit board (PCB) with one or more components on it to a substrate through an interposer board. The interposer board has compressible connectors through it. The connectors through the interposer board are compression-based connector pins that extends above and below the interposer board to make electrical contact between the PCB and the substrate. The system can include a plate to secure the PCB to the substrate and compress the compression-based connectors of the interposer board.

The interposer with the through-board compression connectors can be applied to a memory on package (MOP) architecture to provide high memory speed and low power. Instead of needing to directly solder the memory to the package topside, the system can removably connect the memory to the package substrate, allowing memory replacement. In one example, the implementation can include an interposer directly disposed between the memory module and the substrate. In one example, the implementation can include a compression-attached memory module (CAMM) between the memory module and the interposer.

It will be understood that the interposer directly disposed between the memory module and the substrate would have the same pinout or the same contact layout as the memory module. Thus, the connectors in the interposer can be straight through, without signal routing in the interposer board. Rather than lateral signal routing, the signals on the top of the substrate have the same layout as the signals on the bottom of the substrate, as the connectors extend through the board from one signal layout location to a corresponding signal layout location on the other side.

With the CAMM, the system can include routing, such as lateral signal routing, connecting signals from contacts on one side of the CAMM board to corresponding contacts on the other side of the CAMM board, where at least some of the contacts are located at a different relative location instead of being in a location directly opposite the contact on the other side of the board. Some contacts with corresponding signals can be directly opposite each other on different sides of the CAMM board. Other contacts may be directly opposite each other on different sides of the CAMM board and have different signals instead of corresponding signals.

With a CAMM board or without a CAMM board, in one example, the memory module can be attached on a package substrate on a same side as a processor device is mounted. Instead of needing to solder the CAMM board (if one is used) or the memory module (if a CAMM board is not used), the interposer enables removably connecting the memory to the package substrate. In one example, when the system includes a CAMM board, the memory module can be soldered to the CAMM board.

The system can include a plate to secure the memory and the interposer (and optionally the CAMM board) to the package substrate. The plate can be referred to as a bolster plate or a shield. In one example, the This invention is to create a package architecture with CAMM module attach on package top side, side by side with CPU die replacing Memory direct soldered down on package. A bolster plate is placed on top of CAMM module and stretch towards the board side to direct heat from memory down to platform.

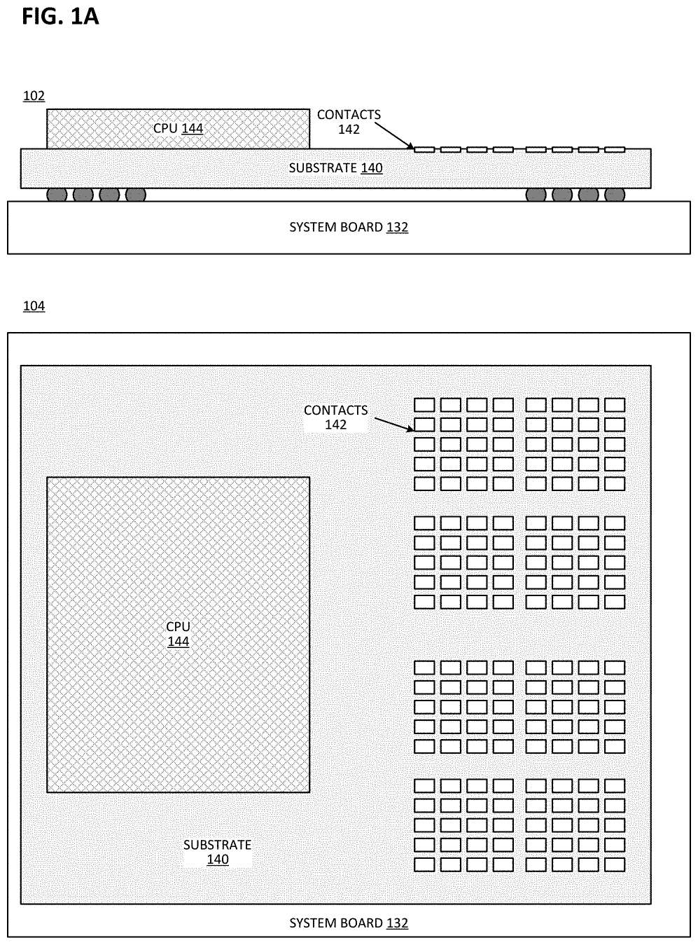

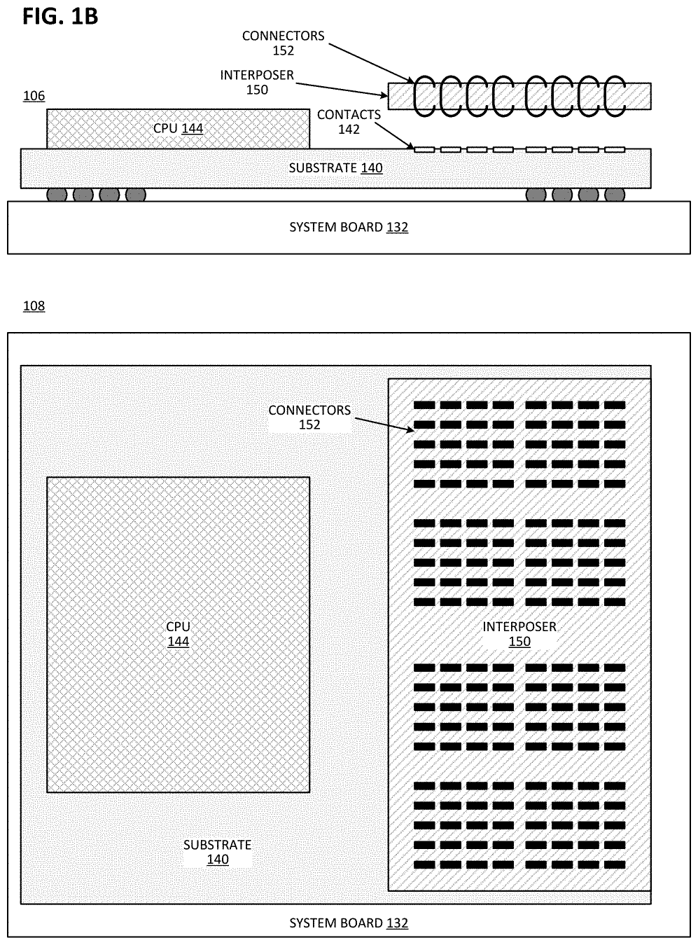

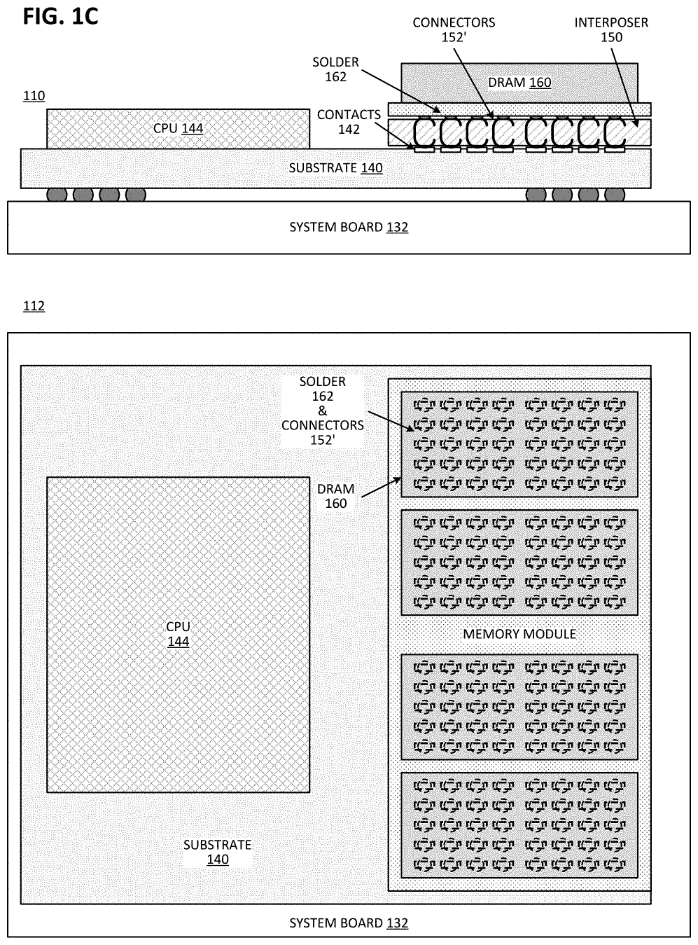

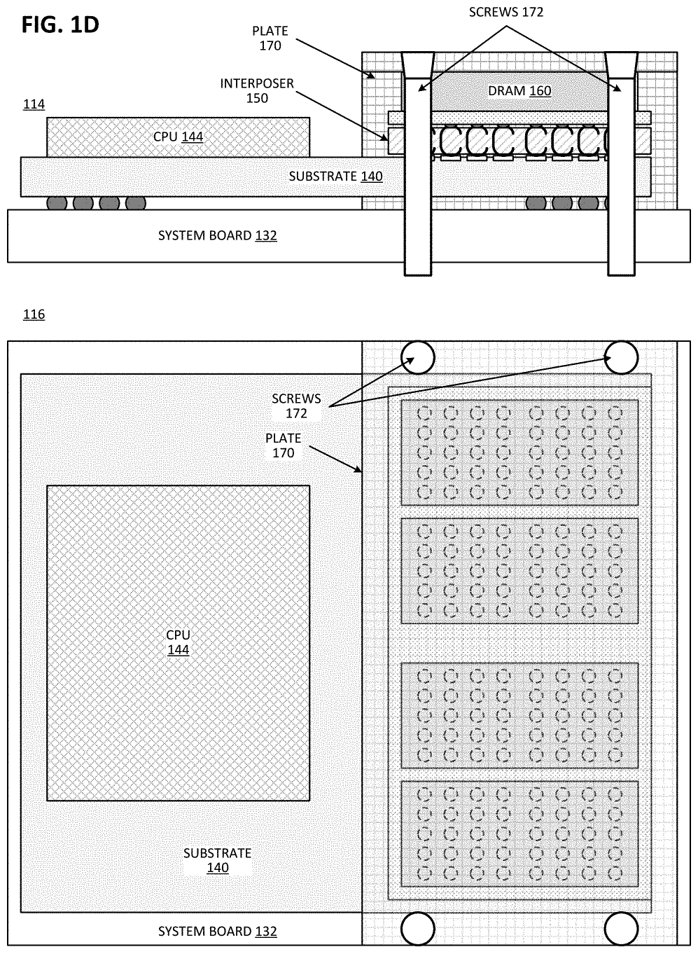

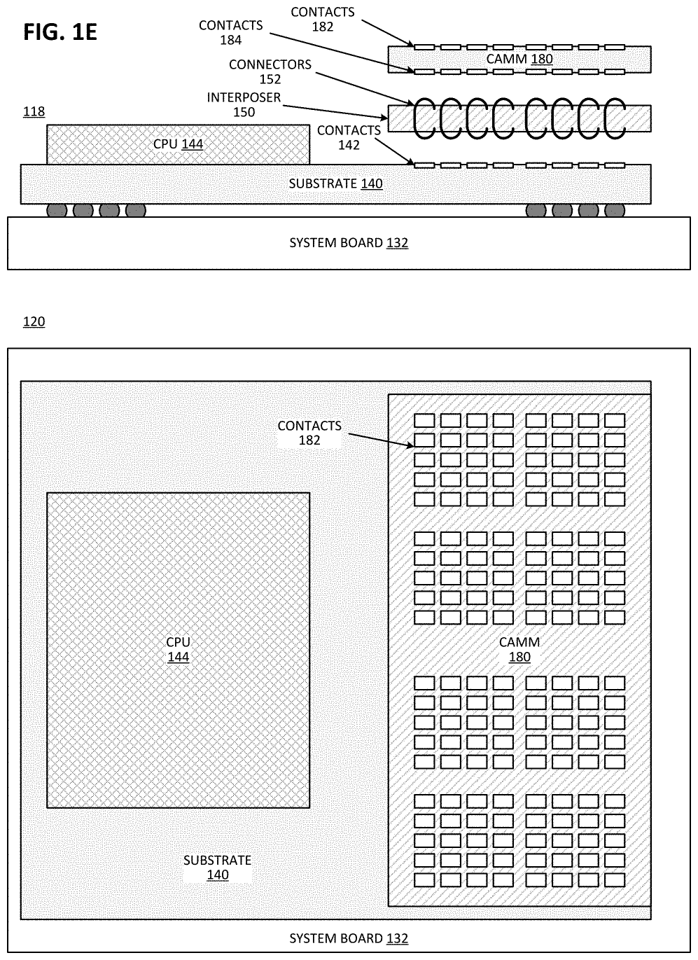

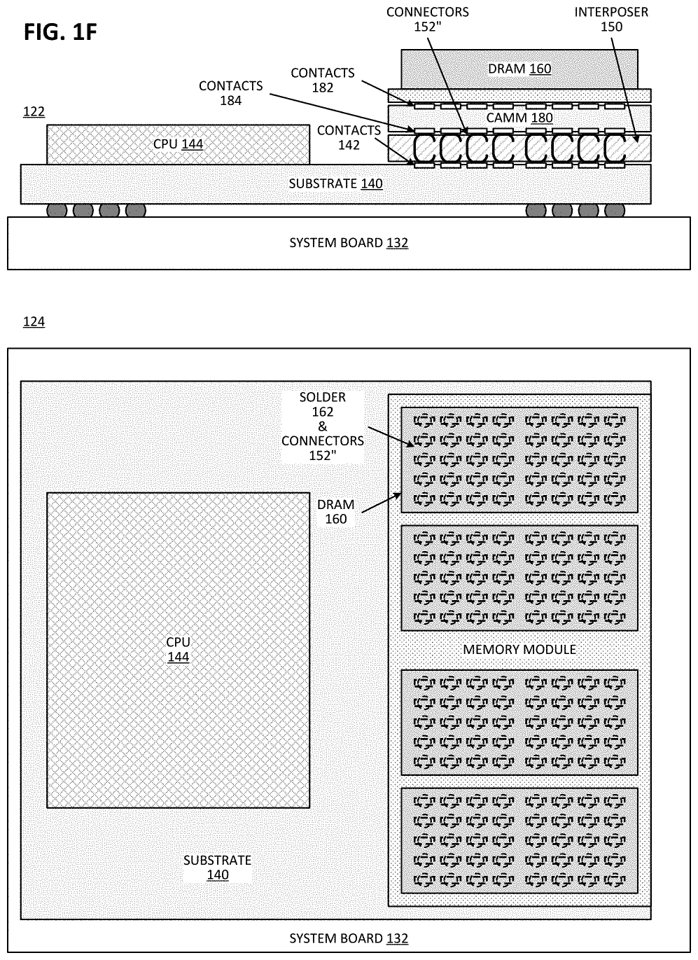

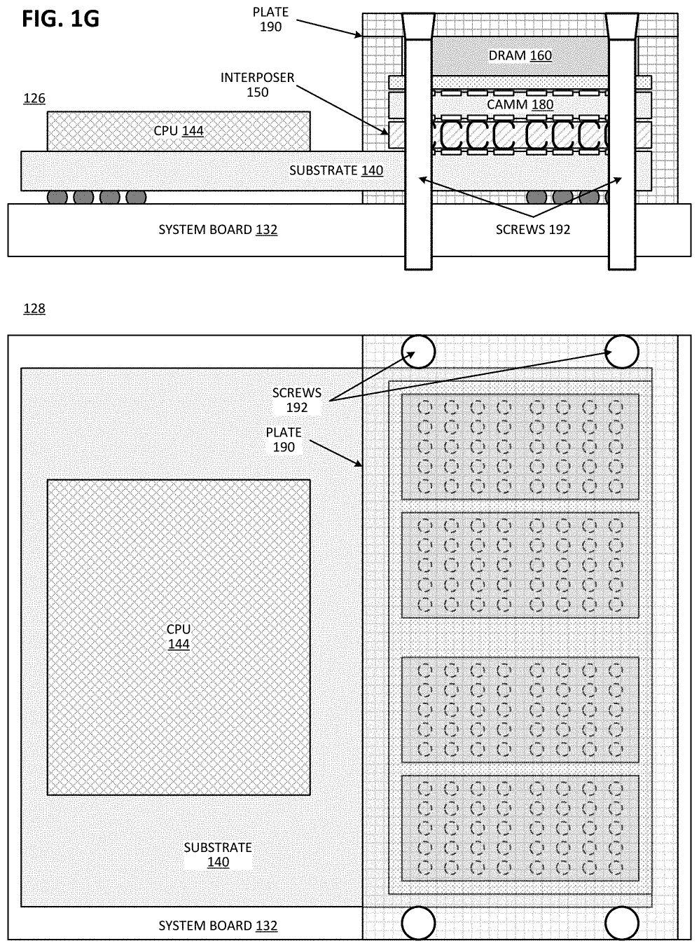

FIG. 1A illustrates diagrams of an example of a circuit substrate for a system. View 102 is a cutaway view of the circuit including system board 132 with substrate 140 mounted on the system board. Substrate 140 includes a compute unit mounted on the substrate. View 104 is a plan view of the circuit. It will be understood that the components, their layouts, and their interconnects are not necessarily to scale. View 102 and view 104 are merely representative of the components of the system.

System board 132 represents a printed circuit board (PCB) or other circuit board. In one example, system board 132 represents a primary system board for a computing device. In one example, system board 132 represents a computer system motherboard.

In one example, substrate 140 represents a PCB or other circuit board. In one example, substrate 140 represents a system on a chip (SOC) package. The SOC package can be a compute SOC, having a compute unit and memory. The package can be a semiconductor substrate to mount multiple dies, tiles, modules, or a combination of these. Substrate 140 is illustrated with solder balls to interconnect to system board 132.

CPU (central processing unit) 144 represents a compute unit mounted on substrate 140. While the compute unit is specifically shown as a CPU, other compute units can be used. In one example, the compute unit on substrate 140 is a graphics processing unit (GPU). In one example, the compute unit on substrate 140 is a field programmable gate array (FPGA). In one example, the compute unit on substrate 140 is an accelerator compute unit or special-purpose compute unit.

Contacts 142 represent the pads or contacts on substrate to receive a module board. The layout illustrated in view 104 represents a layout for an example of a memory module board.

FIG. 1B illustrates diagrams of an example of a circuit substrate for a system in accordance with FIG. 1A. View 106 is a cutaway view of the circuit of view 102 including interposer 150. View 108 is a plan view of the circuit in accordance with view 104. It will be understood that the components, their layouts, and their interconnects are not necessarily to scale.

Interposer includes connectors 152, which can be referred to as connectors, connector pins, through-board connectors, through-board contacts, or other designation. Connectors 152 are compression-based connectors that extend past at least one surface of the interposer board. In one example, connectors 152 include a portion that extends past the top surface of interposer 150, which would be toward a module board when assembled in the system. In one example, connectors 152 include a portion extend past the bottom surface of interposer 150, which would be toward substrate 140 when assembled in the system. In one example, connectors 152 include a first portion that extends past the top surface of interposer 150 and a second portion that extends past the bottom surface of interposer 150.

When compressed, connectors 152 compress towards the middle of interposer 150. If one portion of the connector extends past a surface of interposer 150, that portion will compress toward the surface. If connectors 152 include portions extending past both surfaces, the portions will compress toward the respective surface past which they extend. In one example, connectors 152 compress to have a vertical height approximately equal to the vertical height of the board of interposer 150.

As illustrated in view 106, connectors 152 have a “C-shape”. The C-shape refers to the fact that connectors 152 generally have a loop shape, with the loop open on one side to make shape like the capital letter C. Other shapes are possible. Certain alternative shapes are described in more detail below. It will be understood that the C-shape can look like a C at one cross-section, and can have a width from a different perspective of the connector. In one example, connectors 152 are wires or ribbon wires having a loop shape. View 108 illustrates an example of a top perspective of connectors 152. In one example, the top view of the connectors is a nominally rectangular shape as illustrated in view 108.

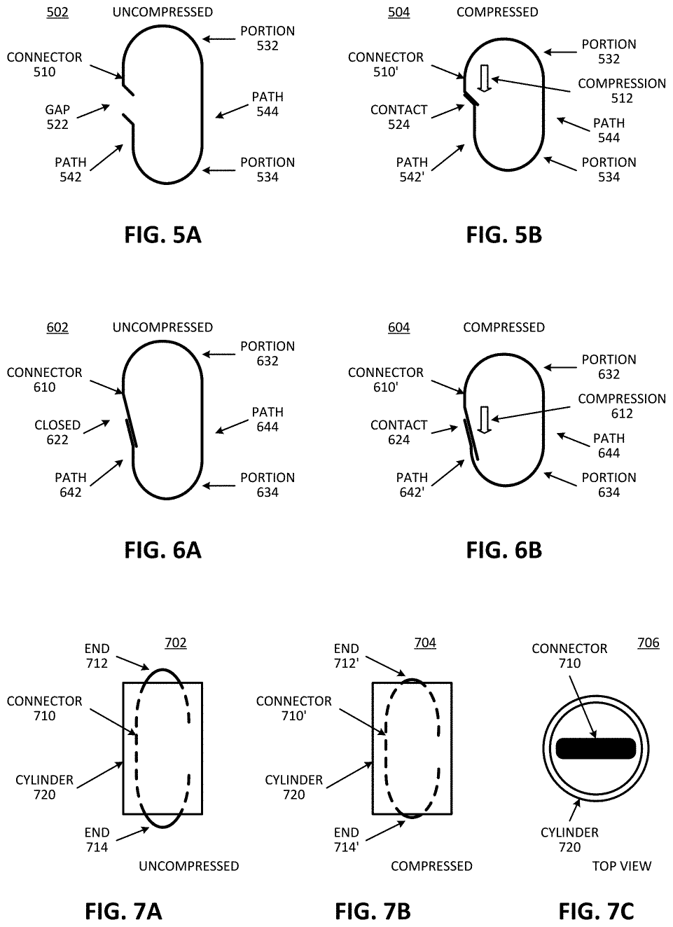

The C-shaped connector pin of connectors 152 can reduce the pin length in the connector relative to connectors that connect through inserting a module board edge into a connector slot. The reduction in pin length reduces crosstalk between neighboring signals, improving EMI performance for high speed communication. In one example, as described in more detail below with respect to FIGS. 5A, 5B, 6A, and 6B, connectors 152 can have self-contact of the connector pin. Self-contact of the connector pin forms a loop within the pin itself. The closed loop connector pin can then allow the signal to flow at the path closer to ground to form a shorter return path. When the signal pin electrical path is closer to the ground pin, the shorter return path improves crosstalk reduction.

Interposer 150 can be referred to as a compression mounted technology (CMT) connector. CMT can refer to an assembly that has connectors/connector pins that compress in response to pressure applied to the assembly. The pressure holds the assembly together and the compression of the connector pins can provide electrical connection between the two terminals to be interconnected, such as between solder bumps/balls and pads/contacts, or between two sets of pads/contacts, or between two sets of solder bumps/balls.

FIG. 1C illustrates diagrams of an example of a circuit for a system in accordance with FIG. 1B. View 110 is a cutaway view of the circuit of view 106 including a memory module, showing the assembly mounted on substrate 140. View 112 is a plan view of the circuit in accordance with view 108. It will be understood that the components, their layouts, and their interconnects are not necessarily to scale.

View 110 illustrates a memory module with dynamic random access memory (DRAM) 160 interconnected to substrate 140 through interposer 150. The DRAM device can be one of multiple DRAM devices. View 112 illustrates the memory module with four DRAMs 160. Solder 162 represents solder balls or solder bumps on the bottom of the memory module. The solder represents a ballout/pinout of DRAM 160. In one example, solder 162 represents solder bumps on the memory module. In one example, solder 162 represents simply the contacts/pads to which solder could be applied to surface mount the memory module. Interposer 150 can connect with the contacts on the memory module to electrically interconnect it to substrate 140.

The ballout/pinout of DRAM 160 can be in accordance with a standard. In one example, DRAM 160 is a memory device compatible with a double data rate version 5 (DDR5) standard. In one example, DRAM 160 is a memory device compatible with a low power double data rate (LPDDR) standard. DRAMs 160 are mounted on a memory module board. In one example, the memory module board is a PCB. In one example, the memory module board can be a substrate, such as a semiconductor substrate on which memory tiles are disposed.

View 110 illustrates connectors 152′ being compressed versions of connectors 152. Even though the drawings are not necessarily to scale, the drawings illustrate that connectors 152′ have less z-height than connectors 152 because they are compressed. View 112 illustrates an example of how solder 162 and connectors 152′ can overlap. The dashed lines represent the fact that the DRAMs 160 would be visible in the plan view of view 112, and solder 162 in contact with connectors 152′ is between the module board and substrate 140. Connector 152′ enable interposer 150 to connect DRAMs 160 to contacts 142. In view 110 and view 112, solder 162 provides a pinout or a pin map for DRAMs 160, and contacts 142 have corresponding pinout/pin map. Contacts 142 provide open pads on the package topside for interposer 150, which represents an example of a CMT connector.

While not specifically illustrated, in one example, connectors 152 are enclosed within a cylinder. An example of a connector enclosed in a cylinder is discussed below in more detail with respect to FIGS. 7A, 7B, and 7C. The cylinder can be any material to surround the connector. Enclosing the connector in a conductor can further improve the EMI performance of the device.

With the CMT connection of the memory module to substrate 140, a system with memory on package can allow upgradability of the memory by the user, modularity of the system by the manufacturer and supplier, and serviceability of the system in the event of memory failure. The system can provide the upgradability, modularity, and serviceability in a form factor compatible with mobile and compact systems. Additionally, the connections do not have exposed edges that could be subject to oxidization, and the connectors do not have long leads that could otherwise create electromagnetic interference at high frequency communication.

FIG. 1D illustrates diagrams of an example of a circuit for a system in accordance with FIG. 1C. View 114 is a cutaway view of the circuit of view 110 including a memory module, showing the assembly mounted on substrate 140. View 116 is a plan view of the circuit in accordance with view 112. It will be understood that the components, their layouts, and their interconnects are not necessarily to scale.

The circuit can include a plate, such as a bolster plate, to secure DRAMs 160 and the memory module, as well as interposer 150 to contacts 142 of substrate 140. When secured, connectors 152′ of interposer 150 are compressed, providing electrical interconnection between the memory module and substrate 140.

In view 114, plate 170 is shown in a cutaway fashion, where the top of the plate is above DRAMs 160. In one example, plate 170 includes side walls that extend from the top of the plate down to system board 132. In one example, instead of side walls, plate 170 can be secured through posts that extend from the plate to system board 132.

Screws 172 secure plate 170 to system board 132, or secure plate 170 through system board 132 to fasteners on the back side (bottom side) of system board 132. View 114 does not specifically illustrate such fasteners. Screws 172 can be referred to as retention screws that hold plate 170 to a system PCB upon system assembly.

In one example, in addition to provide the mechanical/structural function of securing the memory module to substrate, plate 170 can have a composition that enables good heat transfer. Plate 170 can act as a heat spreader for DRAMs 160. In one example, both the composition of plate 170 and screws 172 allows heat transfer from DRAMs 160 to system board 132, or to a thermal solution above plate 170, or to both the system board and to a thermal solution. In one example, screws 172 make electrical and thermal contact with a ground plane of system board 132, improving the spread of heat to the system board. Spreading the heat from the memory module down to the system board can reduce thermal crosstalk between CPU 144 and the memory module.

FIG. 1E illustrates diagrams of an example of a circuit for a system in accordance with FIG. 1B. View 118 is a cutaway view of the circuit of view 106 including a compression attached memory module (CAMM) board. View 120 is a plan view of the circuit in accordance with view 108. It will be understood that the components, their layouts, and their interconnects are not necessarily to scale.

Directly attaching the memory module with interposer 150 to substrate 140 assumes that the layout of contacts 142 corresponds to the layout of contacts on the bottom of the memory module. CAMM 180 allows routing between the bottom of the memory module to different locations, to align signals with corresponding contacts that have a different location in the contact layout. Thus, CAMM 180 can allow horizontal routing of the signals to different locations of the layout.

CAMM 180 includes contacts 182 on one surface and contacts 184 on the opposite surface. In one example, contacts 182 are on a surface of CAMM 180 that faces the memory module and contacts 184 are on a surface of CAMM 180 that faces interposer 150. Thus, connectors 152 make electrical contact with contacts 184, which provides an electrical connection from contacts 182 to contacts 142 of substrate 140. Contacts 142 can be a land grid array memory (LGAM) connection on substrate 140, which can receive a memory module direct-attached by soldering it down on the LGAM. An LGAM connection assumes vertical connections, without lateral routing. Use of CAMM 180 can provide lateral routing to align signal to the pinout of contacts 142.

FIG. 1F illustrates diagrams of an example of a circuit for a system in accordance with FIG. 1B. View 122 is a cutaway view of the circuit of view 118 including a memory module, showing the assembly mounted on substrate 140. View 124 is a plan view of the circuit in accordance with view 120. It will be understood that the components, their layouts, and their interconnects are not necessarily to scale.

View 122 illustrates a memory module with dynamic random access memory (DRAM) 160 interconnected to substrate 140 through CAMM 180 and interposer 150. The DRAM device can be one of multiple DRAM devices. View 124 illustrates the memory module with four DRAMs 160. Solder 162 represents solder balls or solder bumps on the bottom of the memory module. CAMM 180 connects contacts 182 to the memory module, and can route the pinout of the memory module to align signals with a different pinout of contacts 142. Interposer 150 can connect with contacts 184 on CAMM 180 to electrically interconnect it to substrate 140.

View 122 illustrates connectors 152″ being compressed versions of connectors 152. Even though the drawings are not necessarily to scale, the drawings illustrate that connectors 152″ have less z-height than connectors 152 because they are compressed. View 124 illustrates an example of how solder 162 and connectors 152″ can overlap. The dashed lines represent the fact that the DRAMs 160 would be visible in the plan view of view 124, and solder 162 in contact with connectors 152″ is between the module board and substrate 140, through CAMM 180 and interposer 150.

FIG. 1G illustrates diagrams of an example of a circuit for a system in accordance with FIG. 1F. View 126 is a cutaway view of the circuit of view 122 including a memory module, showing the assembly mounted on substrate 140. View 128 is a plan view of the circuit in accordance with view 124. It will be understood that the components, their layouts, and their interconnects are not necessarily to scale.

The circuit can include a plate, such as a bolster plate, to secure DRAMs 160, the memory module, CAMM 180, and interposer 150 to contacts 142 of substrate 140. When secured, connectors 152″ of interposer 150 are compressed, providing electrical interconnection between the memory module and substrate 140.

In view 126, plate 190 is shown in a cutaway fashion, where the top of the plate is above DRAMs 160. Plate 190 can be a plate in accordance with any example of plate 170. Plate 190 could have different dimensions than plate 170 to accommodate the increased height due to the inclusion of CAMM 180. Screws 192 can be in accordance with any example of screws 172, where screws 192 can have different dimensions than screws 172 to accommodate the increased height due to the inclusion of CAMM 180.

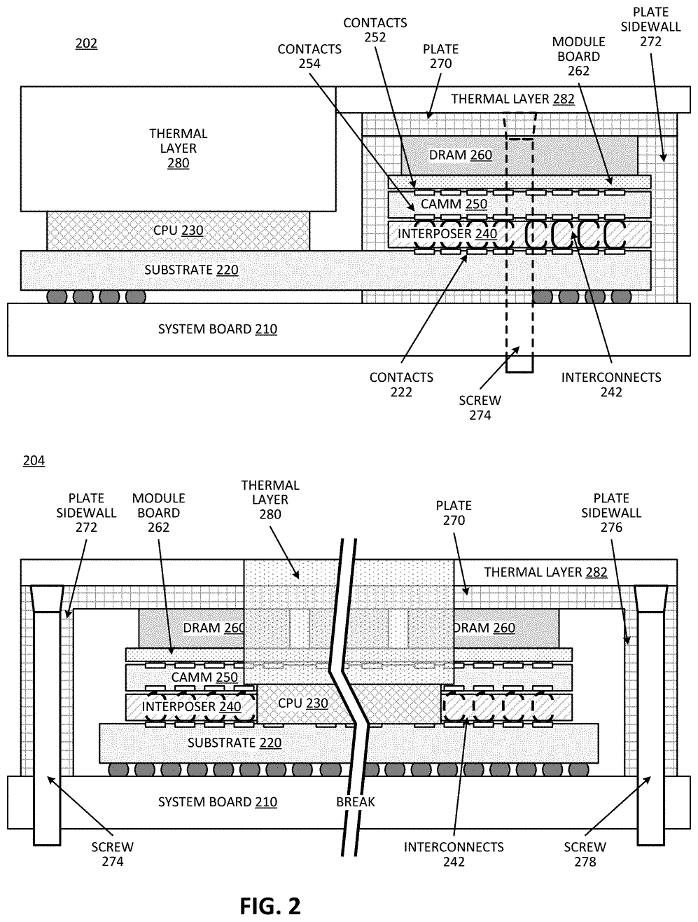

FIG. 2 illustrates diagrams of an example of a circuit for a system in accordance with an example of FIG. 1F. View 202 is a cutaway view of the circuit including a memory module, a CAMM module, and an interposer, showing the assembly mounted on substrate 220. View 204 is a cutaway view of the circuit of view 202, as looking at CPU 230 from what is the left side of view 202. It will be understood that the components, their layouts, and their interconnects are not necessarily to scale.

System board 210 represents an example of a system PCB or motherboard. Substrate 220 is mounted on system board 210. Substrate 220 represents a package substrate, which could be an SOC substrate, and includes contacts 222 as open contacts to receive a memory module. CPU 230 represents a processing unit mounted directly on substrate 220.

The system includes a memory module with DRAMs 260 to mount on substrate 220. Instead of directly soldering the memory module onto contacts 222, the system includes interposer 240 and optionally includes CAMM 250 between the memory module and substrate 220.

The circuit can include a plate (alternatively can be a shield or a cover) to secure DRAMs 260 and the memory module, as well as interposer 240 (and CAMM 250 if the CAMM is included) to contacts 222 of substrate 220. Interposer 240 can be an interposer in accordance with any example provided, which includes compression based connectors (interconnects 242) to provide straight through signaling from the top side of the interposer board to the bottom side of the interposer board. CAMM 250 can be a CAMM in accordance with any example provided, which provides routing to align signals for different contact layouts.

As illustrated, interconnects 242 are compressed. Interconnects 242 provide electrical interconnection between contacts 222 of substrate 220 and contacts 254 of CAMM 250, if the CAMM is included, or between contacts 222 and contacts of module board 262 when the CAMM is not included. The memory module includes module board 262 and DRAMs 260 mounted on module board 262. When CAMM 250 is included, module board 262 can be soldered to contacts 252 of CAMM 250, making a CAMM memory module.

In view 202, plate 270 is shown in a cutaway fashion, where the top of the plate is above DRAMs 260. In one example, plate 170 includes side walls, including sidewall 272, that extend from the top of the plate down to system board 210. In one example, instead of side walls, plate 270 can be secured through posts that extend from the top part of the plate to system board 210.

Screw 274 secures plate 270 to system board 210, or secures plate 270 through system board 210 to fasteners on the back side (bottom side) of system board 210. View 202 does not specifically illustrate such fasteners. Multiple screws can be included per sidewall to secure plate 270 to system board 210. In one example, the system includes one screw per sidewall to secure plate 270. View 202 illustrates screw 274 in dashed lines to represent the fact that it is positioned behind the components in that view, extending through plate sidewall 272.

In view 202, thermal layer 280 is over CPU 230, and will extend vertically to a heat spreader or other thermal solution. Thermal layer 280 has high thermal conductivity to fill the gap between CPU 230 and the heat spreader for the system. In one example, the system can include thermal layer 282 over plate 270 to help spread heat from the memory module. In one example, thermal layer 282 is not included, and the system spreads the heat from the memory module to system board 210 through plate sidewall 272.

View 204 illustrates that the system can include multiple DRAMs 260 on the memory module, connected through interposer 240 and CAMM 250. Thus, module board 262 has multiple DRAMs 260. For simplicity in showing the circuit, there is a break, which means all DRAMs 260 are not fully shown.

View 204 illustrates optional thermal layer 282 over plate 270. View also illustrates thermal layer 280 over CPU 230. View 204 illustrates screw 274 in plate sidewall 272 and screw 278 in plate sidewall 276. Plate sidewall 272 and plate sidewall 276 extend from a top of plate 270 to system board 210.

In one example, as an alternative to sidewalls on plate 270, the system can include structures (e.g., posts, standoffs) that extend from the top of plate 270 to system board 210. In one example, the structures can be physically connected to plate 270, such as through welding or soldering. In one example, the structures can be physically coupled to plate 270 through an adhesive. Whether physically integrated or in physical contact, in one example, the structures have high thermal conductivity to aid in transferring heat from the memory devices through plate 270 to system board 210. In one example, heat transfer occurs through plate 270 and screw 274.

A DRAM device soldered directly onto substrate 220 would create thermal crosstalk with CPU 230, which would degrade the performance of the CPU. The operating temperature of DRAMs can be approximately 85-100 C, which is higher than the operating temperature of CPU 230. In one example, plate 270 has a composition to provide high thermal conductivity, as well as screw 274 and screw 278 having high thermal conductivity to transfer heat from the memory module to system board 210. In one example, the system also includes the optional thermal layer 282 to further enhance the ability of the system to remove heat from the memory.

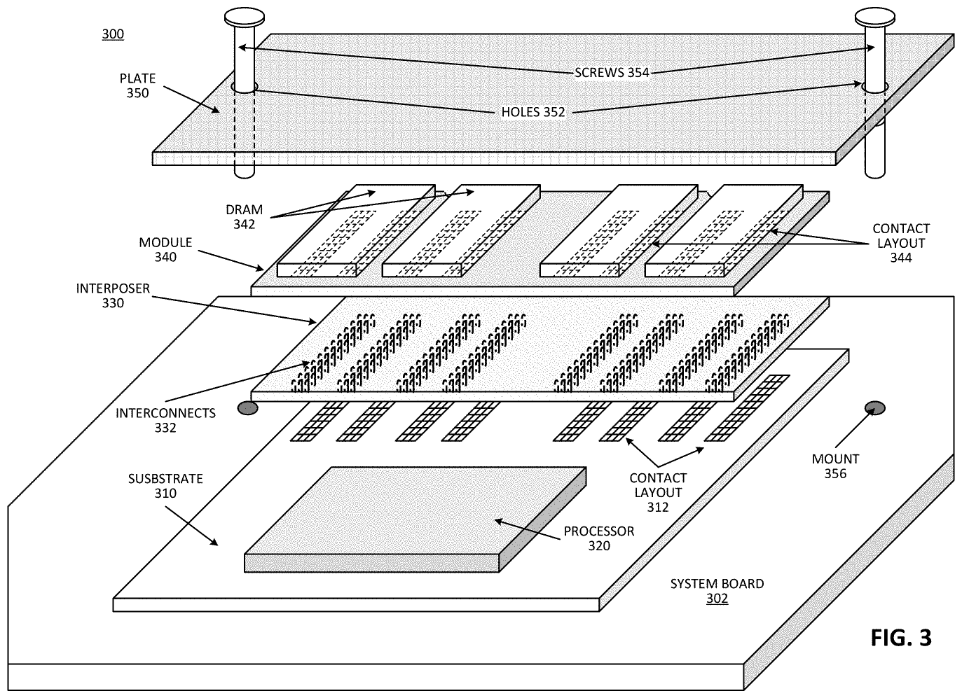

FIG. 3 is a block diagram of an example of a system in which an interposer has C-shaped compression connectors. The features of system 300 are to be understood as representative, and do not necessarily reflect the scale of a real system. In some instances, certain features are exaggerated for purposes of labeling or identification of the features. The layouts are also not necessarily reflective of an actual implementation (e.g., in terms of number of contacts), but are representative of the correspondence of contacts between different boards/substrates.

System 300 includes module 340 to interconnect with substrate 310. Module 340 includes one or more components to interconnect with substrate 310, and can thus be referred to as a component board. In one example, module 340 includes memory devices, represented by DRAMs 342, which can represent any of a wide variety of volatile system memory or graphics memory. Substrate 310 is mounted on system board 302.

In one example, substrate 310 represents an SOC. Substrate 310 includes processor 320 to execute system functions in system 300. Processor 320 can execute an operating system (OS) that controls the operation of system 300 or one or more applications that control the flow of operations and data in system 300. In one example, processor 320 represents a central processing unit (CPU). In one example, processor 320 represents a graphics processing unit (GPU). In one example, processor 320 represents a visual processing unit (VPU) or other artificial intelligence (AI) processing unit. Processor 320 can include one core or multiple cores.

In an implementation where module 340 represents a memory module, system 300 can provide high memory density and high memory speed for each compute unit of substrate 310. The ability to provide high memory density and high memory speed enables system 300 to improve maximum multithreaded performance.

In one example, the PCB of module 340 is a carrier of memory devices of system 300, represented by DRAM devices 342. System 300 illustrates contact layout 344 of module 340 to represent the ball out or pin out of DRAMs 342. As illustrated, contact layout 344 can represent a ball out of the PCB of module 340. While not specifically illustrated in system 300, if there is a difference in signal layout between contact layout 344 of module 340 and contact layout 312 of substrate 310, system 300 can include a CAMM module.

In one example, system 300 includes interposer 330, which represents an interposer connector board to enable a high speed connection of module 340 to substrate 310, while also being removable. The removable nature of module 340 enables system 300 to be upgraded. For example, module 340 can be replaced with a new module in the case of failure or in the case of increasing to a higher-performance component or replacing a failed component.

In one example, interposer 330 represents a PCB with contacts on one side (the top side or top surface, which faces module 340) and contacts on the opposite side (the bottom side or bottom surface, which faces substrate 310). Interposer 330 can also include direct through-hole correspondence between the contacts on the top side and the contacts on the bottom side, without routing of signals to different locations on the board or without changing the contact layout with respect to what is presented by module 340. Such routing can be referred to as passthrough routing.

Interposer 330 includes compression-based connectors through the interposer board, represented by interconnects 332. In one example, interconnects 332 are C-shaped connector pins. Interconnects 332 can be in accordance with any example of compression-based connectors provided herein.

Substrate 310 includes contact layout 312 which is a contact array to provide connection points for module 340. In one example, there will be no change in design for substrate 310 between a memory-down configuration and a memory module configuration. Thus, contact layout 312 can match with the pin configuration of contact layout 344 of DRAM devices 342, allowing devices to be soldered directly to the system board, or to have module 340 mounted on the board.

Reference to a layout matching or corresponding to another layout of connectors refers to the signal layout for the contacts. Thus, for a signal in one physical location of a layout on one board, the connector in the corresponding or matching physical location will carry the same signal.

System 300 includes plate 350 to press module 340 and interposer 330 to substrate 310. System 300 can include screws 354 to secure plate 350 to system board 302. Plate 350 can include holes 352 through which screws 354 can pass to secure to a fastener through mount 356. In one example, mount 356 is threaded and can be the fastener. In one example, mount 356 allows screws 354 to pass through to secure with fasteners on the back side of system board 302. System board 302 includes mounts 356 to receive screws 354 for securing plate 350 to the system board.

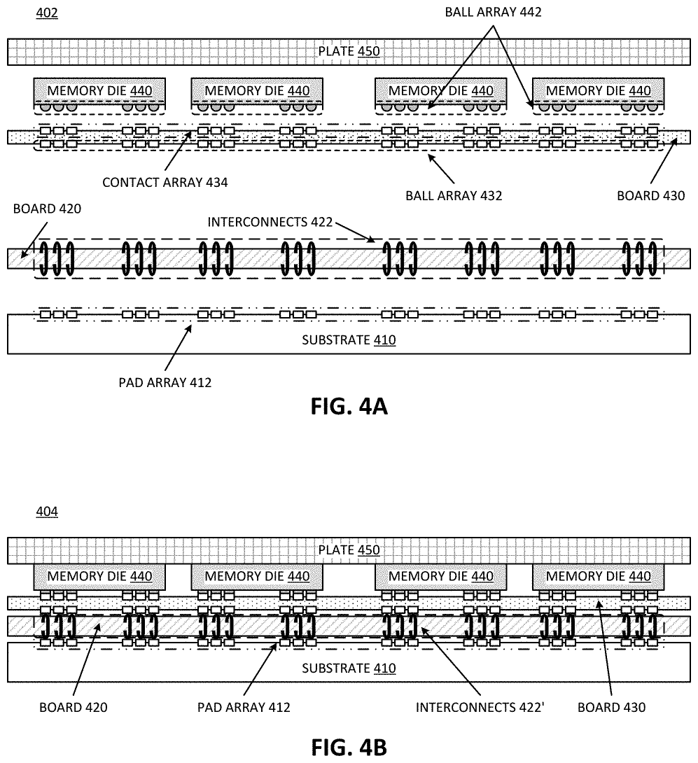

FIG. 4A is a cutaway view of an example of a memory module to connect to a substrate with an interposer having compression-based connectors. The memory module provides one example, and other modules can implement the features related to the cover and the grounding as described.

System 402 illustrates a system in accordance with an example of the systems with compression-based connector pins. Substrate 410 represents a system board or a motherboard. In one example, substrate 410 includes pad array 412 on the surface of the board. Pad array 412 represents pads or connection points on substrate 410. In one example, pad array 412 has a layout that matches the layout of ball array 432 of board 430. In one example, pad array 412 has a different layout than ball array 432, and system 402 can include a CAMM board (not shown).

System 402 includes memory board 430 on which memory dies 440 are mounted. Memory dies 440 represent an example of an integrated circuit component mounted on a module board. Memory dies 440 include ball array 442, which has a pinout or connector configuration that can be defined by specification. Memory dies 440 mount to memory board 430 through contact array 434, which has a connector layout that matches the connector layout of the individual memory dies. Ball array 432 refers to the fact that a module board can have a ball grid array (BGA). The contacts are shown with solder balls in system 402. In one example, the BGA of the module board is left open to connection to interconnects 422.

In one example, system 402 includes board 420, which represents an interposer or interface board. Board 420 includes interconnects 422 on the surface that faces substrate 410. Interconnects 422 represent compression-based connectors in accordance with any example provided herein. In the initial configuration of system 402, interconnects extend above and below board 420 as they are in an uncompressed state.

System 402 includes plate 450 as a cover, plate, or shield for the module that includes memory dies 440, board 430, and board 420. In one example, plate 450 is secured to a system board with screws (not specifically illustrated). Plate 450 can be a plate in accordance with any description herein. Plate 450 when secured can press down on the other modules and board illustrated, which can compress interconnects 422.

FIG. 4B is a cutaway view of an example of a memory module as assembled. System 404 illustrates an example of system 402. System 402 can be referred to as a pre-assembly and system 404 can be referred to as post-assembly.

In system 404, plate 450 is mounted to the system board, covering memory dies 440 mounted to board 430, which is electrically connected to substrate 410 through board 420 (the interposer). The interconnects are compressed, which are identified as interconnects 422′, and they electrically connect pad array 412 to ball array 432.

FIG. 5A illustrates an example of a connector pin that has one side that is physically open when uncompressed. Pin state 502 has connector 510 with gap 522 in path 542. Gap 522 is an opening in the electrical path of path 542 in connector 510 in the uncompressed state of the pin. Connector 510 can be an example of an electrical conductor in a C-shaped connector. Connector 510 includes path 544, which is electrically and physically closed even in the uncompressed state. Connector 510 includes portion 532, which can be one end (e.g., a top end) of the loop or C shape, and portion 534, which can be the other end (e.g., a bottom end) of the loop or C shape.

FIG. 5B illustrates an example of the closed loop connector pin of FIG. 5A, which changes from open to closed when compressed. The arrow in pin state 504 indicates compression 512, indicating the application of compression to the pin. In response to compression 512, the connector closes together, making contact 524 where gap 522 was. The closed connector is indicated as connector 510′. Thus, in response to compression 512, the physical opening of path 542 becomes a closed loop, and the path becomes path 542′. Connector 510 has a starting shape of pin state 502, where connector 510 is in pin state 502 at rest. Under compression the pin will be in pin state 504, closing the gap and causing connector 510′ to contact itself in a loop with two electrical paths. With the compression, one or both ends can compress toward the middle of connector 510′. Portion 532′ represents the potential different position of the one end, and portion 534′ represent the potential different position of the other end.

FIG. 6A illustrates an example of a connector pin that has both side of the loop physically closed when uncompressed. Pin state 602 has connector 610 with closed portion 622 in path 642. Thus, in pin state 602, path 642 is physically and electrically closed. Closed portion 622 is a connection of connector 610 with itself, but has a movable part that can move in response to compression of the pin. Pin state 602 represents the pin at rest, where connector 610 is closed, with some overlap of the connector at one portion of the loop of connector 610. Connector 610 can be an example of an electrical conductor in a C-shaped conductor, although it is already a complete physical loop. Connector 610 includes path 644, which is electrically and physically closed in the uncompressed state. Connector 610 includes portion 632, which can be one end (e.g., a top end) of the loop or C shape, and portion 634, which can be the other end (e.g., a bottom end) of the loop or C shape.

FIG. 6B illustrates an example of the closed loop connector pin of FIG. 6A, which remains closed as it compresses. The arrow in pin state 604 indicates compression 612, indicating the application of compression to the pin. In response to compression 612, the overlapped part of the connector closes farther together. The compression connector is indicated as connector 610′. The connector can be made to slide along itself at the portion of connector 610′ labeled contact 624. In response to compression 612, the space enclosed by the loop of the pin can be made smaller, thus going from a closed loop to a smaller loop in response to compression of the connector. Connector 610′ has two electrical paths, path 642 and path 644. With the compression, one or both ends can compress toward the middle of connector 610′. Portion 632′ represents the potential different position of the one end, and portion 634′ represent the potential different position of the other end.

FIG. 7A illustrates an example of an uncompressed connector enclosed in a cylinder. Pin state 702 has connector 710 with an electrical conductor in a C-shape. A C-shaped connector can have an electrical and physical path through one side of the connector, with the other side open. Thus, a C-shape can make an electrical connection and have an open shape to allow the connector to compress. Connector 710 is enclosed within cylinder 720. Pin state 702 is an uncompressed state of connector 710. In one example, connector 710 has end 712 that extends past one end of cylinder 720 and end 714 that extends past the other end of cylinder 720.

In one example, connector 710 only extends away from cylinder at one end. Thus, end 712 could protrude only enough from cylinder 720 to make contact with the pad/contact to which is should electrically connect, and end 714 can extend past the end of cylinder 720 in the uncompressed state. In the compressed state, the extended end could compress toward the end of the cylinder, protruding from the end of cylinder 720 enough to make an electrical connection, but otherwise being compressed into cylinder 720.

FIG. 7B illustrates an example of a compressed connector enclosed in a cylinder. Pin state 704 represents a compressed state of the connector of FIG. 7A. In response to compression, one or both ends of the connector compress. Connector 710′ represents the connector when compressed. End 712′ represents a compressed end of connector 710. In one example, end 712′ can represent a state of end 712 for an end that does not compress. End 714′ represents a compressed end of connector 710. In one example, end 714′ can represent a state of end 714 for an end that does not compress. It will be understood that in response to compression the gap/opening on the one side of the connector gets smaller even if it does not close all the way.

FIG. 7C illustrates an example of a compressible connector enclosed in a cylinder. View 706 represents a top view of the connector of FIG. 7A. In one example, cylinder 720 is an open tube having a generally circular or oval cross section. Connector 710 can be enclosed within cylinder 720. It will be understood that connector 710 can be connected to a wall of cylinder 720 when a cylinder is used. In an example where cylinder 720 is not used, the connector can be connected to the board or to a structure of the board of the interposer.

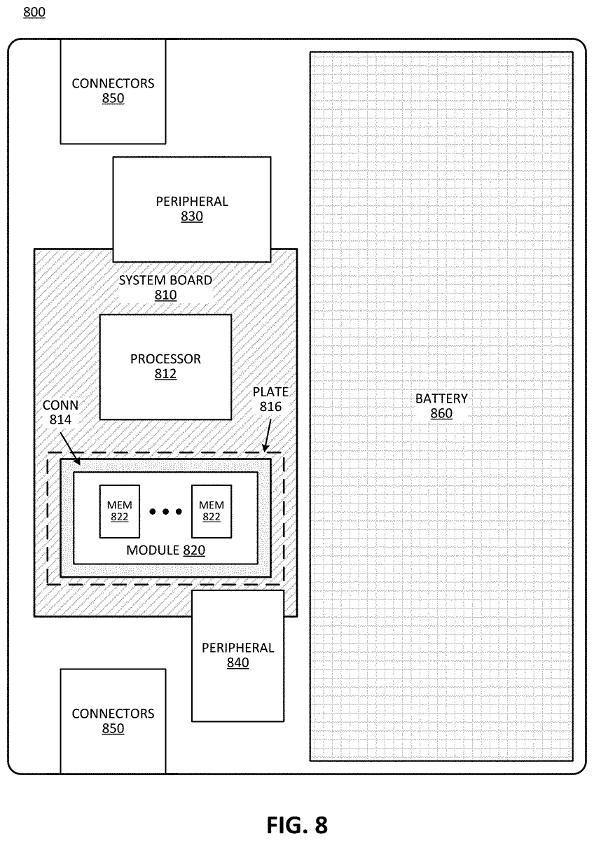

FIG. 8 is a block diagram of an example of a computer system with a connector having an interposer with compression-based connectors. System 800 represents a computing system or a computing device. For example, system 800 can be a laptop computer, a tablet computer, a smart phone or other handheld electronic device, or a two-in-one device. The display for the device is not explicitly shown in system 800, but can be a screen that covers device, or can be a display that connects via hinge, built on top of the chassis of system 800, or connect with some other connector (not shown).

In one example, system 800 has a clamshell design, where the processing elements and keyboard are fixed to the display element. In one example, system 800 is a detachable computer, where the processor and display are part of a common unit has a detachable keyboard.

System 800 includes system board 810, which represents a primary PCB to control the operation in system 800. System board 810 can be referred to as a motherboard in certain computer configurations. System board 810 represents a rectangular system board, which is a traditional system board configuration, with a length and a width (x and y axis, not specifically labeled for orientation in system 800).

System board 810 includes processor 812, which represents a host processor or main processing unit for system 800. In one example, processor 812 is a multicore processor. Processor 812 can be a central processing unit (CPU) or system on a chip (SOC) that includes a CPU or other processor. In one example, processor 812 can include a graphics processing unit (GPU), which can be the same as the primary processor, or separate from the primary processor.

System board 810 includes operational memory or system memory for the computing device. The operational memory generally is, or includes, volatile memory, which has indeterminate state if power is interrupted to the memory. In one example, system 800 includes memory provided by module 820. Module 820 illustrates a module that includes multiple memory devices or memory chips, represented by memory (MEM) 822. Module 820 can be a memory module in accordance with any example herein.

Module 820 interconnects with system board 810 via a connector array of an interposer board that has C-shaped connector pins, in accordance with any example provided. In one example, module 820 connects to system board 810 through a substrate shared with processor 812, and module 820 is connected to the substrate through an interposer board. In one example, module 820 is connected to system board 810 through the interposer, without a separate substrate. Either connected directly to system board 810 or connected through a substrate to system board 810, in one example, the system further includes a CAMM board to provide routing from module 820 to system board 810 (or to the substrate, if the module is mounted to system board 810 through a separate substrate). Connector (CONN) 814 represents the connector assembly with the interposer and plate 816 and optionally with the CAMM board. Connector 814 connects module 820 to system board 810 through compression, in accordance with any example provided, such as securing plate 816 to system board 810.

System 800 includes one or more peripherals connected to system board 810. Peripheral 830 ad peripheral 840 represent different peripherals that could be included in system 800. The size and number of the peripherals can be different in different system configurations. In one example, system 800 includes a solid state drive (SSD) as a peripheral device. In one example, system 800 includes a computation accelerator as a peripheral device. In one example, system 800 includes a wireless communication module or other network interface. A wireless communication module can be or include WiFi, Bluetooth (BT), WWAN (wireless wide area network) such as cellular, or other wireless communication.

System 800 includes connectors 850, which represent I/O (input/output) connectors to devices external to system 800. For example, connectors 850 can be or include USB (universal serial bus) connectors, video connectors such as HDMI (high definition media interface), company-proprietary connectors, or other I/O connectors.

System 800 includes battery 860 to power the system. In one example, system board 810 at least partially overlaps battery 860. It will be understood that the relative size, spacing, and location of components will be different depending on what type of system is implemented for system 800. The size and layout of system 800 is not necessarily intended to be typical or representative of each possible implementation, but illustrates possible components for such an implementation.

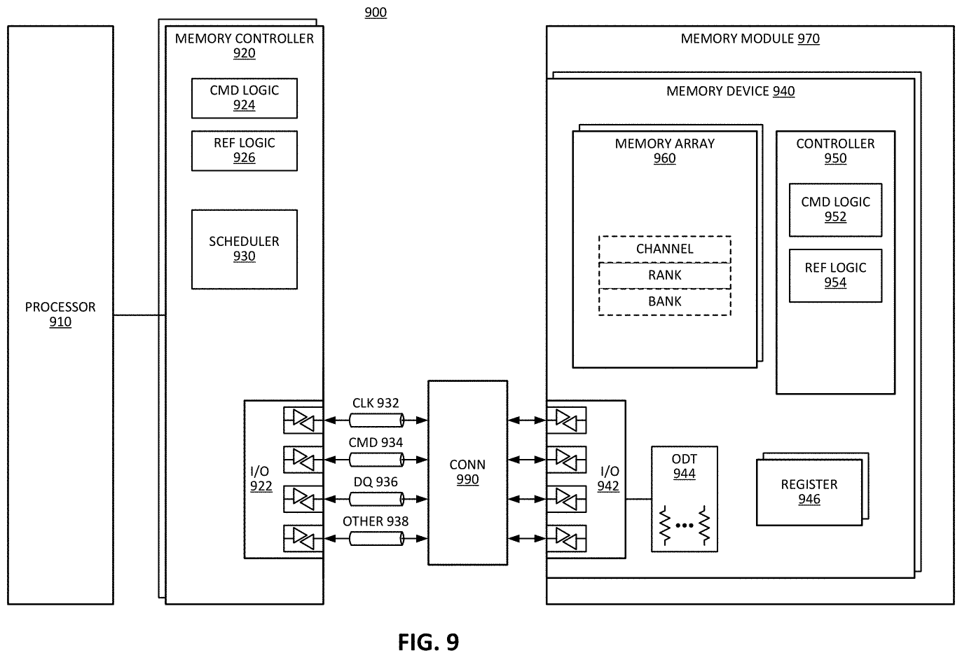

FIG. 9 is a block diagram of an example of a memory subsystem in which a connector having an interposer with compression-based connectors can be implemented. System 900 includes a processor and elements of a memory subsystem in a computing device. System 900 is an example of a system in which memory can be connected to a substrate or a system board in accordance with any example provided.

In one example, system 900 includes connector (CONN) 990 to interconnect memory module 970 and memory devices 940 of the memory module with memory controller 920. Memory controller 920 is disposed on a system board that includes pins, pads, or contacts to connect with memory device 940. Connector (CONN) 990 represents the connector assembly with the interposer and plate and optionally with a CAMM board. Connector 990 connects memory module 970 to the system board through compression in accordance with any example provided.

Processor 910 represents a processing unit of a computing platform that may execute an operating system (OS) and applications, which can collectively be referred to as the host or the user of the memory. The OS and applications execute operations that result in memory accesses. Processor 910 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 900 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 ((HBM version 2), currently in discussion by JEDEC), or others or combinations of memory technologies, and technologies based on derivatives or extensions of such specifications.

Memory controller 920 represents one or more memory controller circuits or devices for system 900. Memory controller 920 represents control logic that generates memory access commands in response to the execution of operations by processor 910. Memory controller 920 accesses one or more memory devices 940. Memory devices 940 can be DRAM devices in accordance with any referred to above. In one example, memory devices 940 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 920 manages a separate memory channel, although system 900 can be configured to have multiple channels managed by a single controller, or to have multiple controllers on a single channel. In one example, memory controller 920 is part of host processor 910, such as logic implemented on the same die or implemented in the same package space as the processor.

Memory controller 920 includes I/O interface logic 922 to couple to a memory bus, such as a memory channel as referred to above. I/O interface logic 922 (as well as I/O interface logic 942 of memory device 940) can include pins, pads, connectors, signal lines, traces, or wires, or other hardware to connect the devices, or a combination of these. I/O interface logic 922 can include a hardware interface. As illustrated, I/O interface logic 922 includes at least drivers/transceivers for signal lines. Commonly, wires within an integrated circuit interface couple with a pad, pin, or connector to interface signal lines or traces or other wires between devices. I/O interface logic 922 can include drivers, receivers, transceivers, or termination, or other circuitry or combinations of circuitry to exchange signals on the signal lines between the devices. The exchange of signals includes at least one of transmit or receive. While shown as coupling I/O 922 from memory controller 920 to I/O 942 of memory device 940, it will be understood that in an implementation of system 900 where groups of memory devices 940 are accessed in parallel, multiple memory devices can include I/O interfaces to the same interface of memory controller 920. In an implementation of system 900 including one or more memory modules 970, I/O 942 can include interface hardware of the memory module in addition to interface hardware on the memory device itself. Other memory controllers 920 will include separate interfaces to other memory devices 940.

The bus between memory controller 920 and memory devices 940 can be implemented as multiple signal lines coupling memory controller 920 to memory devices 940. The bus may typically include at least clock (CLK) 932, command/address (CMD) 934, and write data (DQ) and read data (DQ) 936, and zero or more other signal lines 938. In one example, a bus or connection between memory controller 920 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 900 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 920 and memory devices 940. An example of a serial bus technology is 86106 encoding and transmission of high-speed data with embedded clock over a single differential pair of signals in each direction. In one example, CMD 934 represents signal lines shared in parallel with multiple memory devices. In one example, multiple memory devices share encoding command signal lines of CMD 934, and each has a separate chip select (CS_n) signal line to select individual memory devices.

It will be understood that in the example of system 900, the bus between memory controller 920 and memory devices 940 includes a subsidiary command bus CMD 934 and a subsidiary bus to carry the write and read data, DQ 936. In one example, the data bus can include bidirectional lines for read data and for write/command data. In another example, the subsidiary bus DQ 936 can include unidirectional write signal lines for write and data from the host to memory, and can include unidirectional lines for read data from the memory to the host. In accordance with the chosen memory technology and system design, other signals 938 may accompany a bus or sub bus, such as strobe lines DQS. Based on design of system 900, or implementation if a design supports multiple implementations, the data bus can have more or less bandwidth per memory device 940. For example, the data bus can support memory devices that have either a x4 interface, a x8 interface, a x16 interface, or other interface. The convention “xW,” where W is an integer that refers to an interface size or width of the interface of memory device 940, which represents a number of signal lines to exchange data with memory controller 920. The interface size of the memory devices is a controlling factor on how many memory devices can be used concurrently per channel in system 900 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 940 and memory controller 920 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 940 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 940 represent memory resources for system 900. In one example, each memory device 940 is a separate memory die. In one example, each memory device 940 can interface with multiple (e.g., 2) channels per device or die. Each memory device 940 includes I/O interface logic 942, which has a bandwidth determined by the implementation of the device (e.g., x16 or x8 or some other interface bandwidth). I/O interface logic 942 enables the memory devices to interface with memory controller 920. I/O interface logic 942 can include a hardware interface, and can be in accordance with I/O 922 of memory controller, but at the memory device end. In one example, multiple memory devices 940 are connected in parallel to the same command and data buses. In another example, multiple memory devices 940 are connected in parallel to the same command bus, and are connected to different data buses. For example, system 900 can be configured with multiple memory devices 940 coupled in parallel, with each memory device responding to a command, and accessing memory resources 960 internal to each. For a Write operation, an individual memory device 940 can write a portion of the overall data word, and for a Read operation, an individual memory device 940 can fetch a portion of the overall data word. The remaining bits of the word will be provided or received by other memory devices in parallel.

In one example, memory devices 940 are disposed directly on a motherboard or host system platform (e.g., a PCB (printed circuit board) on which processor 910 is disposed) of a computing device. In one example, memory devices 940 can be organized into memory modules 970. In one example, memory modules 970 represent dual inline memory modules (DIMMs). In one example, memory modules 970 represent other organization of multiple memory devices to share at least a portion of access or control circuitry, which can be a separate circuit, a separate device, or a separate board from the host system platform. Memory modules 970 can include multiple memory devices 940, and the memory modules can include support for multiple separate channels to the included memory devices disposed on them. In another example, memory devices 940 may be incorporated into the same package as memory controller 920, such as by techniques such as multi-chip-module (MCM), package-on-package, through-silicon via (TSV), or other techniques or combinations. Similarly, in one example, multiple memory devices 940 may be incorporated into memory modules 970, which themselves may be incorporated into the same package as memory controller 920. It will be appreciated that for these and other implementations, memory controller 920 may be part of host processor 910.

Memory devices 940 each include one or more memory arrays 960. Memory array 960 represents addressable memory locations or storage locations for data. Typically, memory array 960 is managed as rows of data, accessed via wordline (rows) and bitline (individual bits within a row) control. Memory array 960 can be organized as separate channels, ranks, and banks of memory. Channels may refer to independent control paths to storage locations within memory devices 940. Ranks may refer to common locations across multiple memory devices (e.g., same row addresses within different devices) in parallel. Banks may refer to sub-arrays of memory locations within a memory device 940. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 940 include one or more registers 944. Register 944 represents one or more storage devices or storage locations that provide configuration or settings for the operation of the memory device. In one example, register 944 can provide a storage location for memory device 940 to store data for access by memory controller 920 as part of a control or management operation. In one example, register 944 includes one or more Mode Registers. In one example, register 944 includes one or more multipurpose registers. The configuration of locations within register 944 can configure memory device 940 to operate in different “modes,” where command information can trigger different operations within memory device 940 based on the mode. Additionally or in the alternative, different modes can also trigger different operation from address information or other signal lines depending on the mode. Settings of register 944 can indicate configuration for I/O settings (e.g., timing, termination or ODT (on-die termination) 946, driver configuration, or other I/O settings).

In one example, memory device 940 includes ODT 946 as part of the interface hardware associated with I/O 942. ODT 946 can be configured as mentioned above, and provide settings for impedance to be applied to the interface to specified signal lines. In one example, ODT 946 is applied to DQ signal lines. In one example, ODT 946 is applied to command signal lines. In one example, ODT 946 is applied to address signal lines. In one example, ODT 946 can be applied to any combination of the preceding. The ODT settings can be changed based on whether a memory device is a selected target of an access operation or a non-target device. ODT 946 settings can affect the timing and reflections of signaling on the terminated lines. Careful control over ODT 946 can enable higher-speed operation with improved matching of applied impedance and loading. ODT 946 can be applied to specific signal lines of I/O interface 942, 922 (for example, ODT for DQ lines or ODT for CA lines), and is not necessarily applied to all signal lines.

Memory device 940 includes controller 950, which represents control logic within the memory device to control internal operations within the memory device. For example, controller 950 decodes commands sent by memory controller 920 and generates internal operations to execute or satisfy the commands. Controller 950 can be referred to as an internal controller, and is separate from memory controller 920 of the host. Controller 950 can determine what mode is selected based on register 944, and configure the internal execution of operations for access to memory resources 960 or other operations based on the selected mode. Controller 950 generates control signals to control the routing of bits within memory device 940 to provide a proper interface for the selected mode and direct a command to the proper memory locations or addresses. Controller 950 includes command logic 952, which can decode command encoding received on command and address signal lines. Thus, command logic 952 can be or include a command decoder. With command logic 952, memory device can identify commands and generate internal operations to execute requested commands.

Referring again to memory controller 920, memory controller 920 includes command (CMD) logic 924, which represents logic or circuitry to generate commands to send to memory devices 940. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 940, memory controller 920 can issue commands via I/O 922 to cause memory device 940 to execute the commands. In one example, controller 950 of memory device 940 receives and decodes command and address information received via I/O 942 from memory controller 920. Based on the received command and address information, controller 950 can control the timing of operations of the logic and circuitry within memory device 940 to execute the commands. Controller 950 is responsible for compliance with standards or specifications within memory device 940, such as timing and signaling requirements. Memory controller 920 can implement compliance with standards or specifications by access scheduling and control.

Memory controller 920 includes scheduler 930, which represents logic or circuitry to generate and order transactions to send to memory device 940. From one perspective, the primary function of memory controller 920 could be said to schedule memory access and other transactions to memory device 940. Such scheduling can include generating the transactions themselves to implement the requests for data by processor 910 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 920 typically includes logic such as scheduler 930 to allow selection and ordering of transactions to improve performance of system 900. Thus, memory controller 920 can select which of the outstanding transactions should be sent to memory device 940 in which order, which is typically achieved with logic much more complex that a simple first-in first-out algorithm. Memory controller 920 manages the transmission of the transactions to memory device 940, and manages the timing associated with the transaction. In one example, transactions have deterministic timing, which can be managed by memory controller 920 and used in determining how to schedule the transactions with scheduler 930.

In one example, memory controller 920 includes refresh (REF) logic 926. Refresh logic 926 can be used for memory resources that are volatile and need to be refreshed to retain a deterministic state. In one example, refresh logic 926 indicates a location for refresh, and a type of refresh to perform. Refresh logic 926 can trigger self-refresh within memory device 940, or execute external refreshes which can be referred to as auto refresh commands) by sending refresh commands, or a combination. In one example, controller 950 within memory device 940 includes refresh logic 954 to apply refresh within memory device 940. In one example, refresh logic 954 generates internal operations to perform refresh in accordance with an external refresh received from memory controller 920. Refresh logic 954 can determine if a refresh is directed to memory device 940, and what memory resources 960 to refresh in response to the command.

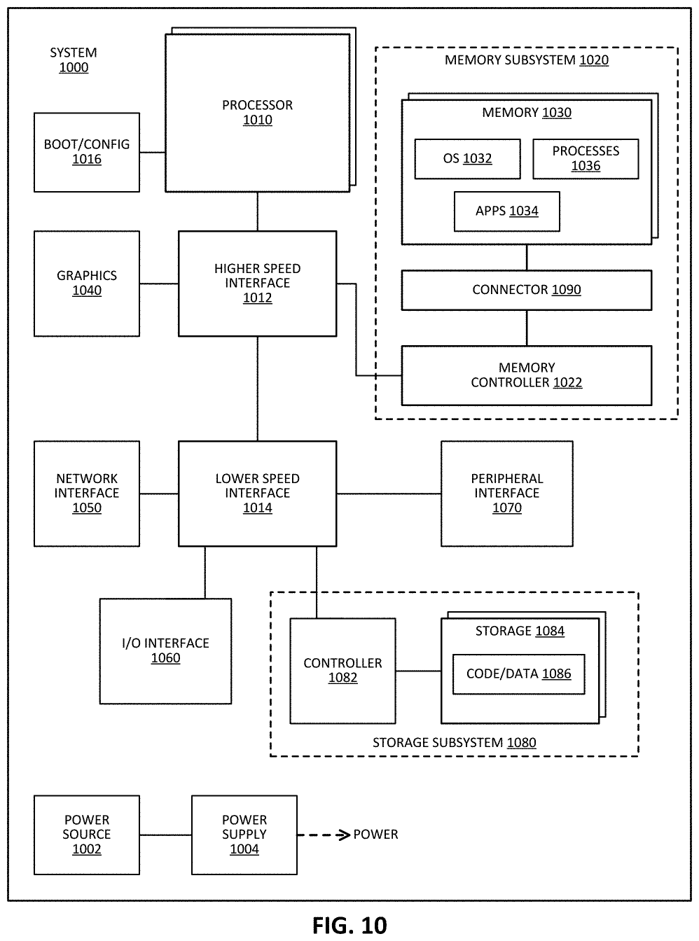

FIG. 10 is a block diagram of an example of a computing system in which a connector having an interposer with compression-based connectors can be implemented. System 1000 represents a computing device in accordance with any example herein, and can be a laptop computer, a desktop computer, a tablet computer, a server, a gaming or entertainment control system, embedded computing device, or other electronic device. System 1000 is an example of a system in which memory can be connected to a substrate or a system board in accordance with any example provided.

In one example, system 1000 includes connector 1090 to interconnect memory 1030 and memory controller 1022. Memory controller 1022 is disposed on a system board that includes pins, pads, or contacts to connect with memory 1030. Connector 1090 represents a connector with closed loop pins in accordance with any example herein. In one example, system 1000 includes connector 1090 to interconnect memory 1030 with memory controller 1022. Memory 1030 can represent memory disposed on a memory module board. Memory controller 1022 is disposed on a system board that includes pins, pads, or contacts to connect with memory 1030. Connector 1090 represents the connector assembly with the interposer and plate and optionally with a CAMM board. Connector 1090 connects memory 1030 to the system board through compression in accordance with any example provided.

System 1000 includes processor 1010 can include any type of microprocessor, central processing unit (CPU), graphics processing unit (GPU), processing core, or other processing hardware, or a combination, to provide processing or execution of instructions for system 1000. Processor 1010 can be a host processor device. Processor 1010 controls the overall operation of system 1000, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1000 includes boot/config 1016, which represents storage to store boot code (e.g., basic input/output system (BIOS)), configuration settings, security hardware (e.g., trusted platform module (TPM)), or other system level hardware that operates outside of a host OS. Boot/config 1016 can include a nonvolatile storage device, such as read-only memory (ROM), flash memory, or other memory devices.

In one example, system 1000 includes interface 1012 coupled to processor 1010, which can represent a higher speed interface or a high throughput interface for system components that need higher bandwidth connections, such as memory subsystem 1020 or graphics interface components 1040. Interface 1012 represents an interface circuit, which can be a standalone component or integrated onto a processor die. Interface 1012 can be integrated as a circuit onto the processor die or integrated as a component on a system on a chip. Where present, graphics interface 1040 interfaces to graphics components for providing a visual display to a user of system 1000. Graphics interface 1040 can be a standalone component or integrated onto the processor die or system on a chip. In one example, graphics interface 1040 can drive a high definition (HD) display or ultra high definition (UHD) display that provides an output to a user. In one example, the display can include a touchscreen display. In one example, graphics interface 1040 generates a display based on data stored in memory 1030 or based on operations executed by processor 1010 or both.

Memory subsystem 1020 represents the main memory of system 1000, and provides storage for code to be executed by processor 1010, or data values to be used in executing a routine. Memory subsystem 1020 can include one or more varieties of random-access memory (RAM) such as DRAM, 3DXP (three-dimensional crosspoint), or other memory devices, or a combination of such devices. Memory 1030 stores and hosts, among other things, operating system (OS) 1032 to provide a software platform for execution of instructions in system 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for system 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010, such as integrated onto the processor die or a system on a chip.

While not specifically illustrated, it will be understood that system 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1000 includes interface 1014, which can be coupled to interface 1012. Interface 1014 can be a lower speed interface than interface 1012. In one example, interface 1014 represents an interface circuit, which can include standalone components and integrated circuitry. In one example, multiple user interface components or peripheral components, or both, couple to interface 1014. Network interface 1050 provides system 1000 the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can exchange data with a remote device, which can include sending data stored in memory or receiving data to be stored in memory.

In one example, system 1000 includes one or more input/output (I/O) interface(s) 1060. I/O interface 1060 can include one or more interface components through which a user interacts with system 1000 (e.g., audio, alphanumeric, tactile/touch, or other interfacing). Peripheral interface 1070 can include any hardware interface not specifically mentioned above. Peripherals refer generally to devices that connect dependently to system 1000. A dependent connection is one where system 1000 provides the software platform or hardware platform or both on which operation executes, and with which a user interacts.

In one example, system 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, NAND, 3DXP, or optical based disks, or a combination. Storage 1084 holds code or instructions and data 1086 in a persistent state (i.e., the value is retained despite interruption of power to system 1000). Storage 1084 can be generically considered to be a “memory,” although memory 1030 is typically the executing or operating memory to provide instructions to processor 1010. Whereas storage 1084 is nonvolatile, memory 1030 can include volatile memory (i.e., the value or state of the data is indeterminate if power is interrupted to system 1000). In one example, storage subsystem 1080 includes controller 1082 to interface with storage 1084. In one example controller 1082 is a physical part of interface 1014 or processor 1010, or can include circuits or logic in both processor 1010 and interface 1014.

Power source 1002 provides power to the components of system 1000. More specifically, power source 1002 typically interfaces to one or multiple power supplies 1004 in system 1000 to provide power to the components of system 1000. In one example, power supply 1004 includes an AC to DC (alternating current to direct current) adapter to plug into a wall outlet. Such AC power can be renewable energy (e.g., solar power) power source 1002. In one example, power source 1002 includes a DC power source, such as an external AC to DC converter. In one example, power source 1002 or power supply 1004 includes wireless charging hardware to charge via proximity to a charging field. In one example, power source 1002 can include an internal battery or fuel cell source.

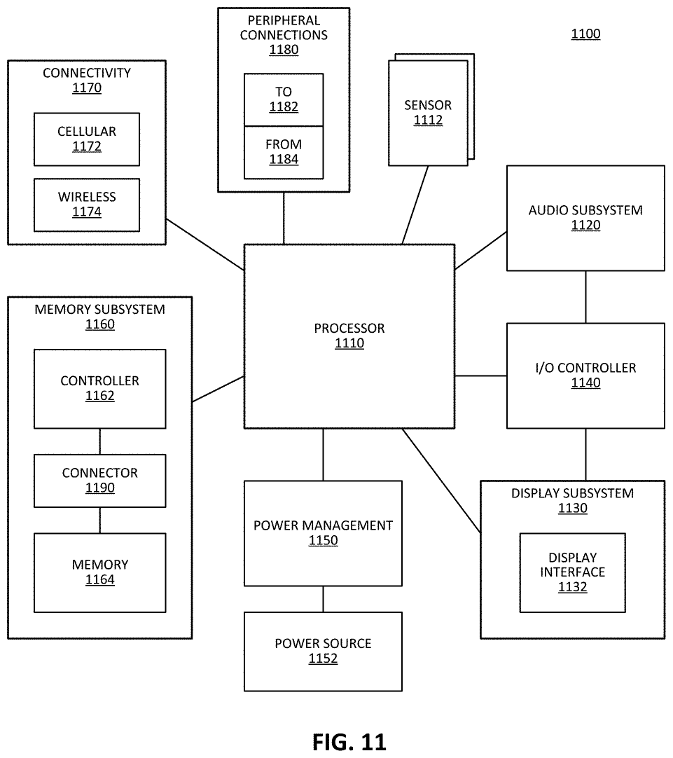

FIG. 11 is a block diagram of an example of a mobile device in which a connector having an interposer with compression-based connectors can be implemented. System 1100 represents a mobile computing device, such as a computing tablet, a mobile phone or smartphone, wearable computing device, or other mobile device, or an embedded computing device. It will be understood that certain of the components are shown generally, and not all components of such a device are shown in system 1100. System 1100 is an example of a system in which memory can be connected to a substrate or a system board in accordance with any example provided.

In one example, system 1100 includes connector 1190 to interconnect memory 1164 and memory controller 1162. Memory controller 1162 is disposed on a system board that includes pins, pads, or contacts to connect with memory 1164. Connector 1190 represents a connector with closed loop pins in accordance with any example herein. In one example, system 1100 includes connector 1190 to interconnect memory 1164 with memory controller 1162. Memory 1164 can represent memory disposed on a memory module board. Memory controller 1162 is disposed on a system board that includes pins, pads, or contacts to connect with memory 1164. Connector 1190 represents the connector assembly with the interposer and plate and optionally with a CAMM board. Connector 1190 connects memory 1164 to the system board through compression in accordance with any example provided.

System 1100 includes processor 1110, which performs the primary processing operations of system 1100. Processor 1110 can be a host processor device. Processor 1110 can include one or more physical devices, such as microprocessors, application processors, microcontrollers, programmable logic devices, or other processing means. The processing operations performed by processor 1110 include the execution of an operating platform or operating system on which applications and device functions are executed. The processing operations include operations related to I/O (input/output) with a human user or with other devices, operations related to power management, operations related to connecting system 1100 to another device, or a combination. The processing operations can also include operations related to audio I/O, display I/O, or other interfacing, or a combination. Processor 1110 can execute data stored in memory. Processor 1110 can write or edit data stored in memory.

In one example, system 1100 includes one or more sensors 1112. Sensors 1112 represent embedded sensors or interfaces to external sensors, or a combination. Sensors 1112 enable system 1100 to monitor or detect one or more conditions of an environment or a device in which system 1100 is implemented. Sensors 1112 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1112 can also include sensors for biometric systems such as fingerprint recognition systems, face detection or recognition systems, or other systems that detect or recognize user features. Sensors 1112 should be understood broadly, and not limiting on the many different types of sensors that could be implemented with system 1100. In one example, one or more sensors 1112 couples to processor 1110 via a frontend circuit integrated with processor 1110. In one example, one or more sensors 1112 couples to processor 1110 via another component of system 1100.

In one example, system 1100 includes audio subsystem 1120, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1100, or connected to system 1100. In one example, a user interacts with system 1100 by providing audio commands that are received and processed by processor 1110.

Display subsystem 1130 represents hardware (e.g., display devices) and software components (e.g., drivers) that provide a visual display for presentation to a user. In one example, the display includes tactile components or touchscreen elements for a user to interact with the computing device. Display subsystem 1130 includes display interface 1132, which includes the particular screen or hardware device used to provide a display to a user. In one example, display interface 1132 includes logic separate from processor 1110 (such as a graphics processor) to perform at least some processing related to the display. In one example, display subsystem 1130 includes a touchscreen device that provides both output and input to a user. In one example, display subsystem 1130 includes a high definition (HD) or ultra-high definition (UHD) display that provides an output to a user. In one example, display subsystem includes or drives a touchscreen display. In one example, display subsystem 1130 generates display information based on data stored in memory or based on operations executed by processor 1110 or both.

I/O controller 1140 represents hardware devices and software components related to interaction with a user. I/O controller 1140 can operate to manage hardware that is part of audio subsystem 1120, or display subsystem 1130, or both. Additionally, I/O controller 1140 illustrates a connection point for additional devices that connect to system 1100 through which a user might interact with the system. For example, devices that can be attached to system 1100 might include microphone devices, speaker or stereo systems, video systems or other display device, keyboard or keypad devices, buttons/switches, or other I/O devices for use with specific applications such as card readers or other devices.

As mentioned above, I/O controller 1140 can interact with audio subsystem 1120 or display subsystem 1130 or both. For example, input through a microphone or other audio device can provide input or commands for one or more applications or functions of system 1100. Additionally, audio output can be provided instead of or in addition to display output. In another example, if display subsystem includes a touchscreen, the display device also acts as an input device, which can be at least partially managed by I/O controller 1140. There can also be additional buttons or switches on system 1100 to provide I/O functions managed by I/O controller 1140.

In one example, I/O controller 1140 manages devices such as accelerometers, cameras, light sensors or other environmental sensors, gyroscopes, global positioning system (GPS), or other hardware that can be included in system 1100, or sensors 1112. The input can be part of direct user interaction, as well as providing environmental input to the system to influence its operations (such as filtering for noise, adjusting displays for brightness detection, applying a flash for a camera, or other features).

In one example, system 1100 includes power management 1150 that manages battery power usage, charging of the battery, and features related to power saving operation. Power management 1150 manages power from power source 1152, which provides power to the components of system 1100. In one example, power source 1152 includes an AC to DC (alternating current to direct current) adapter to plug into a wall outlet. Such AC power can be renewable energy (e.g., solar power, motion based power). In one example, power source 1152 includes only DC power, which can be provided by a DC power source, such as an external AC to DC converter. In one example, power source 1152 includes wireless charging hardware to charge via proximity to a charging field. In one example, power source 1152 can include an internal battery or fuel cell source.

Memory subsystem 1160 includes memory device(s) 1162 for storing information in system 1100. Memory subsystem 1160 can include nonvolatile (state does not change if power to the memory device is interrupted) or volatile (state is indeterminate if power to the memory device is interrupted) memory devices, or a combination. Memory 1160 can store application data, user data, music, photos, documents, or other data, as well as system data (whether long-term or temporary) related to the execution of the applications and functions of system 1100. In one example, memory subsystem 1160 includes memory controller 1164 (which could also be considered part of the control of system 1100, and could potentially be considered part of processor 1110). Memory controller 1164 includes a scheduler to generate and issue commands to control access to memory device 1162.

Connectivity 1170 includes hardware devices (e.g., wireless or wired connectors and communication hardware, or a combination of wired and wireless hardware) and software components (e.g., drivers, protocol stacks) to enable system 1100 to communicate with external devices. The external device could be separate devices, such as other computing devices, wireless access points or base stations, as well as peripherals such as headsets, printers, or other devices. In one example, system 1100 exchanges data with an external device for storage in memory or for display on a display device. The exchanged data can include data to be stored in memory, or data already stored in memory, to read, write, or edit data.

Connectivity 1170 can include multiple different types of connectivity. To generalize, system 1100 is illustrated with cellular connectivity 1172 and wireless connectivity 1174. Cellular connectivity 1172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), 5G, or other cellular service standards. Wireless connectivity 1174 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1180 include hardware interfaces and connectors, as well as software components (e.g., drivers, protocol stacks) to make peripheral connections. It will be understood that system 1100 could both be a peripheral device (“to” 1182) to other computing devices, as well as have peripheral devices (“from” 1184) connected to it. System 1100 commonly has a “docking” connector to connect to other computing devices for purposes such as managing (e.g., downloading, uploading, changing, synchronizing) content on system 1100. Additionally, a docking connector can allow system 1100 to connect to certain peripherals that allow system 1100 to control content output, for example, to audiovisual or other systems.

In addition to a proprietary docking connector or other proprietary connection hardware, system 1100 can make peripheral connections 1180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

In general with respect to the descriptions herein, in one aspect, an apparatus includes: a first printed circuit board (PCB) including a component mounted on a first PCB first surface and contacts of a first PCB second surface; an interposer board having connector pins through the interposer board to connect the contacts of the first PCB second surface to a substrate, the connector pins being compression-based connector pins having a first portion extending past a first surface of the interposer board; and a plate to cover the first PCB and secure the first PCB and the interposer board to the substrate, the plate to compress the connector pins of the interposer board, including to compress the first portion toward the first surface of the interposer board.

In accordance with an example of the apparatus, in one example, the substrate is to be mounted on a second PCB, wherein the plate is to be secured with screws to the second PCB, connecting to a ground plane of the second PCB. In accordance with any preceding example of the apparatus, in one example, the connector pins have a conductor in a C-shape, wherein, when uncompressed, the C-shape comprises a loop with a gap on one side, where the gap is to get smaller in response to compression of the connector pins. In accordance with any preceding example of the apparatus, in one example, the connector pins have a conductor in a C-shape, wherein, when uncompressed, the C-shape comprises a loop with a gap on one side, where the gap is to close in response to compression of the connector pins. In accordance with any preceding example of the apparatus, in one example, the connector pins have a conductor in a closed loop shape, wherein, when uncompressed, the closed loop has two closed electrical paths, wherein the conductor is to slide along itself on one side to make a smaller closed loop in response to compression of the connector pins. In accordance with any preceding example of the apparatus, in one example, the first PCB comprises a memory module and the substrate comprises a compute system on a chip (SOC). In accordance with any preceding example of the apparatus, in one example, the compute SOC is mounted on a second PCB, wherein the second PCB comprises a system board. In accordance with any preceding example of the apparatus, in one example, the apparatus includes: a compression attached memory module (CAMM) board to which the memory module is mounted to CAMM board first surface contacts, and wherein the interposer board is to connect between CAMM board second surface contacts and the compute SOC, wherein the CAMM board includes routing to electrically align a first pinout of the memory module to a second pinout of the compute SOC, where the first pinout is different from the second pinout. In accordance with any preceding example of the apparatus, in one example, the memory module includes multiple dynamic random access memory (DRAM) devices. In accordance with any preceding example of the apparatus, in one example, the DRAM devices comprise DRAM devices compatible with a double data rate version 5 (DDR5) standard. In accordance with any preceding example of the apparatus, in one example, the DRAM devices comprise DRAM devices compatible with a low power double data rate (LPDDR) standard.

In general with respect to the descriptions herein, in one aspect, a computer system includes: a substrate having a processor mounted on the substrate; a system board, wherein the substrate is mounted on the system board; a memory module including multiple memory devices; an interposer board having connector pins through the interposer board to connect the memory module to the substrate, the connector pins being compression-based connector pins having a first portion of a loop extending past a first surface of the interposer board and a second portion of the loop extending past a second surface of the interposer board; and a plate on top of the memory module, to secure to the system board, the plate to secure the memory module and the interposer board to the substrate, the plate to compress the connector pins of the interposer board.

In accordance with an example of the computer system, in one example, the connector pins have a conductor in a C-shape, wherein, when uncompressed, the C-shape comprises a loop with a gap on one side, where the gap is to get smaller in response to compression of the connector pins. In accordance with any preceding example of the computer system, in one example, the connector pins have a conductor in a C-shape, wherein, when uncompressed, the C-shape comprises a loop with a gap on one side, where the gap is to close in response to compression of the connector pins. In accordance with any preceding example of the computer system, in one example, the system board comprises a motherboard. In accordance with any preceding example of the computer system, in one example, the computer system includes: a compression attached memory module (CAMM) board to which the memory module is mounted to CAMM board first surface contacts, and wherein the interposer board is to connect between CAMM board second surface contacts and the substrate, wherein the CAMM board includes routing to electrically align a first pinout of the memory module to a second pinout of the substrate, where the first pinout is different from the second pinout. In accordance with any preceding example of the computer system, in one example, the computer system includes: screws to secure the plate to the system board, the screws electrically connecting to a ground plane of the system board. In accordance with any preceding example of the computer system, in one example, the computer system includes: standoffs that extend from a top of the plate on top of the memory module to the system board through which the screws connect to the system board. In accordance with any preceding example of the computer system, in one example, the plate comprises sidewalls to extend from a top of the plate on top of the memory module to the system board. In accordance with any preceding example of the computer system, in one example, the memory module includes multiple dynamic random access memory (DRAM) devices compatible with a double data rate version 5 (DDR5) standard or DRAM device compatible with a low power double data rate (LPDDR) standard. In accordance with any preceding example of the computer system, in one example, the processor comprises a multicore processor. In accordance with any preceding example of the computer system, in one example, the computer system further includes a display communicatively coupled to the processor of the substrate. In accordance with any preceding example of the computer system, in one example, the computer system further includes a network interface communicatively coupled to the processor of the substrate. In accordance with any preceding example of the computer system, in one example, the computer system further includes a battery to power the computer system.

In general with respect to the descriptions herein, in one aspect, a method includes: mounting a component on a first printed circuit board (PCB) first surface, the first PCB having contacts on a first PCB second surface; and securing a plate to cover the first PCB and secure the first PCB and an interposer board to a substrate, wherein the interposer board includes connector pins through the interposer board to connect the contacts of the first PCB second surface to the substrate, the connector pins being compression-based connector pins having a first portion extending past a first surface of the interposer board, wherein securing the plate compresses the connector pins of the interposer board, including compressing the first portion toward the first surface of the interposer board.

In accordance with an example of the method, in one example, the substrate is mounted on a second PCB, wherein the plate is secured with screws to the second PCB, connecting to a ground plane of the second PCB. In accordance with any preceding example of the method, in one example, the connector pins have a conductor in a C-shape, wherein, when uncompressed, the C-shape comprises a loop with a gap on one side, where the gap shrinks in response to compression of the connector pins. In accordance with any preceding example of the method, in one example, connector pins have a conductor in a C-shape, wherein, when uncompressed, the C-shape comprises a loop with a gap on one side, where the gap closes in response to compression of the connector pins. In accordance with any preceding example of the method, in one example, the connector pins have a conductor in a closed loop shape, wherein, when uncompressed, the closed loop has two closed electrical paths, wherein the conductor slides along itself on one side to make a smaller closed loop in response to compression of the connector pins. In accordance with any preceding example of the method, in one example, the first PCB comprises a memory module and the substrate comprises a compute system on a chip (SOC). In accordance with any preceding example of the method, in one example, the compute SOC is mounted on a second PCB, wherein the second PCB comprises a system board. In accordance with any preceding example of the method, in one example, securing the plate includes securing a compression attached memory module (CAMM) board to which the memory module is mounted to CAMM board first surface contacts, to the interposer board with CAMM board second surface contacts, wherein the CAMM board includes routing to electrically align a first pinout of the memory module to a second pinout of the compute SOC, where the first pinout is different from the second pinout. In accordance with any preceding example of the method, in one example, the memory module includes multiple dynamic random access memory (DRAM) devices. In accordance with any preceding example of the method, in one example, the DRAM devices comprise DRAM devices compatible with a double data rate version 5 (DDR5) standard. In accordance with any preceding example of the method, in one example, the DRAM devices comprise DRAM devices compatible with a low power double data rate (LPDDR) standard.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus, comprising:
a first printed circuit board (PCB) including a component mounted on a first PCB first surface and contacts of a first PCB second surface;
an interposer board having connector pins through the interposer board to connect the contacts of the first PCB second surface to a substrate, the connector pins being compression-based connector pins having a first portion extending past a first surface of the interposer board; and
a plate to cover the first PCB and secure the first PCB and the interposer board to the substrate, the plate to compress the connector pins of the interposer board, including to compress the first portion toward the first surface of the interposer board.

2. The apparatus of claim 1, wherein the substrate is to be mounted on a second PCB, wherein the plate is to be secured with screws to the second PCB, connecting to a ground plane of the second PCB.

3. The apparatus of claim 1, wherein the connector pins have a conductor in a C-shape, wherein, when uncompressed, the C-shape comprises a loop with a gap on one side, where the gap is to get smaller in response to compression of the connector pins.

4. The apparatus of claim 1, wherein the connector pins have a conductor in a C-shape, wherein, when uncompressed, the C-shape comprises a loop with a gap on one side, where the gap is to close in response to compression of the connector pins.

5. The apparatus of claim 1, wherein the connector pins have a conductor in a closed loop shape, wherein, when uncompressed, the closed loop has two closed electrical paths, wherein the conductor is to slide along itself on one side to make a smaller closed loop in response to compression of the connector pins.

6. The apparatus of claim 1, wherein the first PCB comprises a memory module and the substrate comprises a compute system on a chip (SOC).

7. The apparatus of claim 6, wherein the compute SOC is mounted on a second PCB, wherein the second PCB comprises a system board.

8. The apparatus of claim 6, further comprising:
a compression attached memory module (CAMM) board to which the memory module is mounted to CAMM board first surface contacts, and wherein the interposer board is to connect between CAMM board second surface contacts and the compute SOC, wherein the CAMM board includes routing to electrically align a first pinout of the memory module to a second pinout of the compute SOC, where the first pinout is different from the second pinout.

9. The apparatus of claim 8, wherein the memory module includes multiple dynamic random access memory (DRAM) devices.

10. The apparatus of claim 9, wherein the DRAM devices comprise DRAM devices compatible with a double data rate version 5 (DDR5) standard.

11. The apparatus of claim 10, wherein the DRAM devices comprise DRAM devices compatible with a low power double data rate (LPDDR) standard.

12. A computer system comprising:
a substrate having a processor mounted on the substrate;
a system board, wherein the substrate is mounted on the system board;
a memory module including multiple memory devices;
an interposer board having connector pins through the interposer board to connect the memory module to the substrate, the connector pins being compression-based connector pins having a first portion of a loop extending past a first surface of the interposer board and a second portion of the loop extending past a second surface of the interposer board; and
a plate on top of the memory module, to secure to the system board, the plate to secure the memory module and the interposer board to the substrate, the plate to compress the connector pins of the interposer board.

13. The computer system of claim 12, wherein the connector pins have a conductor in a C-shape, wherein, when uncompressed, the C-shape comprises a loop with a gap on one side, where the gap is to get smaller in response to compression of the connector pins.

14. The computer system of claim 12, wherein the connector pins have a conductor in a C-shape, wherein, when uncompressed, the C-shape comprises a loop with a gap on one side, where the gap is to close in response to compression of the connector pins.

15. The computer system of claim 12, wherein the system board comprises a motherboard.

16. The computer system of claim 12, further comprising:
a compression attached memory module (CAMM) board to which the memory module is mounted to CAMM board first surface contacts, and wherein the interposer board is to connect between CAMM board second surface contacts and the substrate, wherein the CAMM board includes routing to electrically align a first pinout of the memory module to a second pinout of the substrate, where the first pinout is different from the second pinout.

17. The computer system of claim 12, further comprising:
screws to secure the plate to the system board, the screws electrically connecting to a ground plane of the system board.

18. The computer system of claim 17, further comprising:
standoffs that extend from a top of the plate on top of the memory module to the system board through which the screws connect to the system board.

19. The computer system of claim 12, wherein the plate comprises sidewalls to extend from a top of the plate on top of the memory module to the system board.

20. The computer system of claim 12, wherein the memory module includes multiple dynamic random access memory (DRAM) devices compatible with a double data rate version 5 (DDR5) standard or DRAM device compatible with a low power double data rate (LPDDR) standard.

21. The computer system of claim 12, wherein one or more of:
the processor comprises a multicore processor;
the computer system further includes a display communicatively coupled to the processor of the substrate;
the computer system further includes a network interface communicatively coupled to the processor of the substrate; or
the computer system further includes a battery to power the computer system.
